(19) United States
(12) Patent Application Publication
(10) Pub. No.: US 2026/0244819 A1
(43) Pub. Date: Aug. 20, 2026

(54) ELECTRONIC APPARATUS, NON-TRANSITORY COMPUTER-READABLE RECORDING MEDIUM, AND CARBON DIOXIDE EMISSION ESTIMATING METHOD

(71) Applicant: KYOCERA DOCUMENT SOLUTIONS INC., OSAKA (JP)

(72) Inventors: RYOTA YAGANE, OSAKA (JP); NAOKI TAKEUCHI, OSAKA (JP); MASAHIRO SUZUKI, OSAKA (JP); MANORI DISSANAYAKE, OSAKA (JP)

(21) Appl. No.: 19/534,772

(22) Filed: Feb. 10, 2026

(30) Foreign Application Priority Data
Feb. 17, 2025 (JP) 2025-023712

(51) Int. Cl. G06F 30/20

(52) U.S. Cl. CPC G06F 30/20

(57) ABSTRACT

An electronic apparatus includes an estimator that obtains an estimated value of carbon dioxide emissions caused when the apparatus executes a job, using a carbon dioxide emission estimating model represented by a formula used to estimate the carbon dioxide emissions, and a setting for the job. The estimating model is represented by the formula in which an expression corresponding to a multiple regression formula used to obtain an estimated value of power consumption caused when the apparatus executes the job, is multiplied by a carbon-dioxide-emission coefficient. A plurality of explanatory variables exists in the estimating model depending on a type of the setting for the job or a state of the apparatus. The variable represents a time feature amount of a time taken for the job or duration of the state. The estimating model represents use frequency or a use period using the time feature amount.

### CROSS-REFERENCE TO RELATED PATENT APPLICATION

This application claims the benefit of Japanese Priority Patent Application JP 2025-023712 filed Feb. 17, 2025, the entire contents of which are incorporated herein by reference.

### FIELD OF THE DISCLOSURE

The present disclosure relates to an electronic apparatus, a carbon dioxide emission estimating system that estimates carbon dioxide emissions of the electronic apparatus, and a non-transitory computer-readable recording that has stored therein a carbon dioxide emission estimating program.

### BACKGROUND OF THE DISCLOSURE

In related art, a carbon dioxide emission estimating system that obtains an estimated value of carbon dioxide emissions of an image forming apparatus is known. The estimated value of the carbon dioxide emissions is obtained as indicated below. A reference power quantity obtained by measuring power consumption in advance is multiplied by a print mode coefficient that corresponds to a print mode representing whether to perform color printing or black-and-white printing, and a value obtained by the multiplication is further multiplied by a layout coefficient that corresponds to a layout representing the number of pages printed on a sheet of paper. Accordingly, power consumption caused when an image forming apparatus executes a single job is obtained. The obtained power consumption is multiplied by carbon dioxide emissions per unit power consumption to obtain the estimated value of the carbon dioxide emissions. Typically, the reference power quantity is, for example, power quantity consumed upon performing, for example, black-and-white printing on a single A4-sized page. The print mode coefficient is set to “1” in a print mode in which black-and-white printing is performed, and is set to a value larger than “1” in a print mode in which color printing is performed. The layout coefficient is set to “1” in the case of “none”, which represents a layout with which a single page of a document is printed on one of sides of a sheet of paper, and is set to “0.5” in the case of “2in1”, which represents a layout with which two pages of the document are printed one of the sides of the sheet of paper. Further, the layout coefficient is set to “0.25” in the case of “4in1”, which represents a layout with which four pages of the document are printed one of the sides of the sheet of paper, and is set to “0.125” in the case of “8in1”, which represents a layout with which eight pages of the document are printed one of the sides of the sheet of paper.

Further, another carbon dioxide emission estimating system that obtains an estimated value of carbon dioxide emissions of an image forming apparatus is known. The estimated value of the carbon dioxide emissions is obtained as indicated below. Power consumption defined for each operation section and determined by a setting for printing is multiplied by the number of times of operation performed by the operation section, where the number of times of operation is determined by the number of sheets of paper printed and the number of sides on which printing is performed. Accordingly, power consumption caused when the image forming apparatus executes a single job is obtained. The obtained power consumption is multiplied by a coefficient of carbon dioxide emissions due to electric power to obtain the estimated value of the carbon dioxide emissions.

### SUMMARY OF THE DISCLOSURE

An electronic apparatus according to an embodiment of the present disclosure includes a carbon dioxide emission estimator that obtains an estimated value of carbon dioxide emissions caused when the electronic apparatus executes a job, using a carbon dioxide emission estimating model represented by a formula used to estimate the carbon dioxide emissions, and a setting for the job. The carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions. With respect to an explanatory variable in the carbon dioxide emission estimating model, there exists a plurality of the explanatory variables depending on a type of the setting for the job or a state of the electronic apparatus. The explanatory variable represents a time feature amount of a time taken for the job or duration of the state. The carbon dioxide emission estimating model represents use frequency or a use period using the time feature amount.

A carbon dioxide emission estimating program according to an embodiment of the present disclosure that has been recorded in a non-transitory computer-readable recording medium is a carbon dioxide emission estimating program that causes a control circuit of an electronic apparatus to operate as a carbon dioxide emission estimator that obtains an estimated value of carbon dioxide emissions caused when the electronic apparatus executes a job, using a carbon dioxide emission estimating model represented by a formula used to estimate the carbon dioxide emissions, and a setting for the job. The carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions. With respect to an explanatory variable in the carbon dioxide emission estimating model, there exists a plurality of the explanatory variables depending on a type of the setting for the job or a state of the electronic apparatus. The explanatory variable represents a time feature amount of a time taken for the job or duration of the state. The carbon dioxide emission estimating model represents use frequency or a use period using the time feature amount.

A carbon dioxide emission estimating method according to an embodiment of the present disclosure is a carbon dioxide emission estimating method that is performed by a carbon dioxide emission estimating program being executed by a control circuit of an electronic apparatus, the carbon dioxide emission estimating method including obtaining an estimated value of carbon dioxide emissions caused when the electronic apparatus executes a job, using a carbon dioxide emission estimating model represented by a formula used to estimate the carbon dioxide emissions, and a setting for the job. The carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions. With respect to an explanatory variable in the carbon dioxide emission estimating model, there exists a plurality of the explanatory variables depending on a type of the setting for the job or a state of the electronic apparatus. The explanatory variable represents a time feature amount of a time taken for the job or duration of the state. The carbon dioxide emission estimating model represents use frequency or a use period using the time feature amount.

These and other objects, features and advantages of the present disclosure will become more apparent in light of the following detailed description of best mode embodiments thereof, as illustrated in the accompanying drawings.

### BRIEF DESCRIPTION OF THE DRAWINGS

FIG. 1 is a block diagram of an example of an image forming apparatus that serves as a carbon dioxide emission estimating system according to an embodiment of the present disclosure.

FIG. 2 illustrates an example of job history information illustrated in FIG. 1.

FIG. 3 is a block diagram of an example of a carbon-dioxide-emission-estimating-model generating system used to generate a carbon dioxide emission estimating model used by the image forming apparatus illustrated in FIG. 1.

FIG. 4 is a flowchart of a method for generating the carbon dioxide emission estimating model used by the image forming apparatus illustrated in FIG. 1.

FIG. 5 is a flowchart of an operation performed by the image forming apparatus of FIG. 1 upon executing a copying job.

FIG. 6 is a flowchart of an operation performed by the image forming apparatus of FIG. 1 upon displaying a total of carbon dioxide emissions.

FIG. 7 is a block diagram of an example of a carbon dioxide emission estimating system according to an embodiment of the present disclosure that is different from the example illustrated in FIG. 1.

### DETAILED DESCRIPTION OF THE EXEMPLARY EMBODIMENTS

The existing carbon dioxide emission estimating systems only provide less accurate estimated values of carbon dioxide emissions of the image forming apparatuses.

In view of the circumstances described above, the present disclosure provides an electronic apparatus, a carbon dioxide emission estimating system, and a carbon dioxide emission estimating program that make it possible to improve the accuracy of an estimated value of carbon dioxide emissions of the electronic apparatus.

Hereinafter, embodiments of the present disclosure will be described with reference to the drawings. In the present embodiment, an image forming apparatus such as a multifunction peripheral is described as an electronic apparatus. However, another type of electronic apparatus may be acceptable.

First, a configuration of an image forming apparatus that serves as a carbon dioxide emission estimating system according to an embodiment of the present disclosure is described.

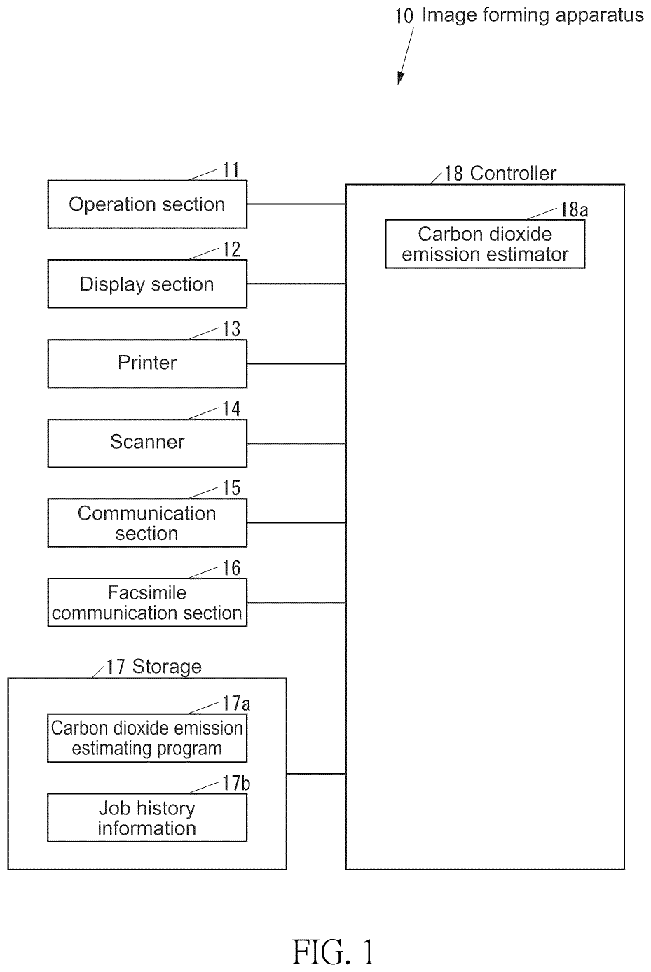

FIG. 1 is a block diagram of an example of an image forming apparatus 10 according to the present embodiment.

As illustrated in FIG. 1, the image forming apparatus 10 is a computer that includes an operation section 11, a display section 12, a printer 13, a scanner 14, a communication section 15, a facsimile communication section 16, a storage 17, and a controller 18. The operation section 11 is an operation device, such as a button, that is used to input various operations. The display section 12 is a display device, such as a liquid crystal display (LCD), that displays thereon various information. The printer 13 is a printing device that prints an image on a recording medium such as a sheet of paper. The scanner 14 is a reading device that reads an image of a document. The communication section 15 is a communication device that communicates with an external apparatus via a network such as a local area network (LAN) or the Internet, or that directly communicates with the external apparatus wirelessly or by wire without any networks. The facsimile communication section 16 is a facsimile device that performs facsimile communication with an external facsimile apparatus (not illustrated) via a communication line such as a public telephone line. The storage 17 is a nonvolatile storage device, such as a semiconductor memory or a hard disk drive (HDD), that stores therein various information. The controller 18 controls the entirety of the image forming apparatus 10.

The storage 17 can store therein a carbon dioxide emission estimating program 17a used to estimate carbon dioxide emissions of the image forming apparatus 10. For example, the carbon dioxide emission estimating program 17a may be installed on the image forming apparatus 10 in process of manufacturing the image forming apparatus 10, may be additionally installed on the image forming apparatus 10 from an external medium such as a Universal-Serial-Bus (USB) memory, or may be additionally installed on the image forming apparatus 10 from the network.

The storage 17 can store therein job history information 17b that stores therein a history of a job executed by the image forming apparatus 10.

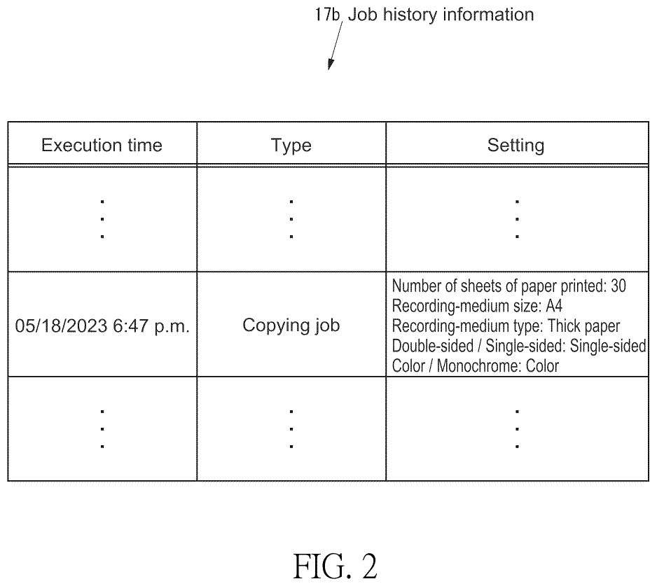

FIG. 2 illustrates an example of the job history information 17b.

As illustrated in FIG. 2, a history stored in the job history information 17b includes, for each job, a time taken to execute the job, the type of the job such as a copying job or a printing job, and a setting for the job. The history stored in the job history information 17b includes all of the information necessary to estimate carbon dioxide emissions using a carbon dioxide emission estimating model described later.

The controller 18 illustrated in FIG. 1 includes, for example, a central processing unit (CPU), a read only memory (ROM) that stores therein a program and various data, and a random access memory (RAM) that is a memory used as a working region for the CPU of the controller 18. The CPU of the controller 18 executes the program stored in the storage 17 or in the ROM of the controller 18.

The controller 18 executes the carbon dioxide emission estimating program 17a to provide a carbon dioxide emission estimator 18a that estimates carbon dioxide emissions of the image forming apparatus 10, and to perform a method for estimating the carbon dioxide emissions.

The carbon dioxide emission estimating model is represented by a formula used by the carbon dioxide emission estimator 18a to estimate carbon dioxide emissions caused when the image forming apparatus 10 executes a single job. The carbon dioxide emission estimating model is represented by the following formula:

$${CO}_{2} emissions = \{ ( {a}_{y} ) {\hat{}}^{{y}^{′}} - {n}_{y} \} \times coefficient of {CO}_{2} emissions \\ ( {y}^{′} = ) {log}_{{a}_{y}} ( y + {n}_{y} ) = a + {\sum }_{k = 1}^{l} {b}_{k}^{t} {t}_{k}^{t} {log}_{{a}_{T}} ( T ) {log}_{{a}_{k}^{t}} ( {x}_{k}^{t} + {n}_{k} ) + {\sum }_{k = 1}^{𝔪} {b}_{k}^{o} {t}_{k}^{o} {log}_{{a}_{k}^{o}} ( {x}_{k}^{o} + {n}_{k} ) + {\sum }_{k = 1}^{n} {t}_{k}^{s} {b}_{k}^{s} {x}_{k}^{s}$$

y represents power consumption, y′ represents logarithmized power consumption, and a represents a constant term.

$${x}_{k}^{t}$$

represents a job-execution-information variable (such as the number of sheets of paper printed or the number of sheets of paper copied) that is related to a TEC value,

$${x}_{k}^{o}$$

represents a job-execution-information variable (such as a percentage of color printing or the number of times of scanning) that is not related to the TES value, and

$${x}_{k}^{s}$$

represents an explanatory variable for a set value (such as light sleep, deep sleep, or a drum-heater setting).

$${t}_{k}^{t} , {t}_{k}^{o} , and {t}_{k}^{s}$$

each represent a time taken for each job (such as printing or copying), or a period of time for which each state (light sleep or deep sleep) remains unchanged. n_{y} and nₖ each represent an offset value for logarithmic transform. a_{y}, a_{T},

$${a}_{k}^{t} , and {a}_{k}^{o}$$

represent bases of respective logarithms. Tₖ represents the TEC value, and

$${b}_{k}^{x}$$

represents a partial regression coefficient.

In the carbon dioxide emission estimating model, an expression in braces on the right side corresponds to a multiple regression formula (hereinafter referred to as a “power consumption estimating model”) used to obtain an estimated value of power consumption caused when the image forming apparatus 10 executes a single job.

The carbon dioxide emission estimator 18a obtains an estimated value of carbon dioxide emissions caused when the image forming apparatus 10 executes a job, using the carbon dioxide emission estimating model represented by the formula used to estimate the carbon dioxide emissions, and the setting for the job.

The carbon dioxide emission estimating model is represented by a formula in which an expression corresponding to a multiple regression formula used to obtain an estimated value of power consumption caused when the image forming apparatus 10 executes a job, is multiplied by a coefficient of carbon dioxide emissions.

With respect to the explanatory variable in the carbon dioxide emission estimating model, there exists a plurality of explanatory variables depending on the type of a setting for a job (such as the number of sheets of paper printed and the number of sheets of paper copied that are related to a total-electricity-consumption (TEC) value; and a percentage of color printing and the number of times of scanning that are not related to the TEC value) or a state of the image forming apparatus 10 (such as light sleep, deep sleep, and a drum-heater setting). The explanatory variable represents a time feature amount of a time taken for a job (such as printing or copying) or duration of the state (light sleep or deep sleep), and the carbon dioxide emission estimating model represents use frequency or a use period using the time feature amount. The multiple regression formula includes a constant term that represents total electric power essentially necessary to execute a job.

A logarithmic transform is applied to each variable. Here, the logarithmic transform is not applied to a variable having a value of zero. Thus, a value obtained by adding, to each variable, a very small positive real number is logarithmized. The base in this case exhibits a positive real number except for one. Further, when actual power consumption is calculated, output logarithmized power consumption is indexed such that the value of the power consumption returns to an original scale value.

This formula makes it possible to estimate, without a power meter, power consumption of the image forming apparatus 10 per day from a set value of the image forming apparatus 10 and job execution information regarding the image forming apparatus 10, and thus to estimate carbon dioxide emissions. The formula represents not only the number of counts per day and a sleep power value of the image forming apparatus 10, but also hours of operation in a day for each status or for each type of job. In other words, the formula according to the present embodiment can represent use frequency or a use period by a time feature amount being introduced as an explanatory variable.

In the carbon dioxide emission estimating model, n is an integer that is greater than or equal to two.

In the carbon dioxide emission estimating model, xₙ, which is an explanatory variable, may exist, for example, depending on the type of setting for a target job.

For example, something that corresponds to the number of sheets of paper printed that represents the number of recording media on which an image is printed on a target job, may be adopted as xₙ. For example, when one document is placed on contact glass to be copied, the number of copies to be set may be treated as the number of sheets of paper printed on a copying job. Further, when a plurality of documents is placed in an automatic document feeder (ADF) to be copied and when the image forming apparatus includes a preview printing function to perform various settings through a preview display screen to copy all of the plurality of documents read in advance, the product of the number of documents read and the number of copies to be set may be treated as the number of sheets of paper printed.

For example, something that corresponds to a recording-medium size that represents a size of a recording medium on which an image is printed on a target job, may be adopted as xₙ. For example, a value of an explanatory variable corresponding to the recording-medium size may be determined according to the recording-medium size, such as five for A4 size and two for A5 size. The value of the explanatory variable corresponding to the recording-medium size may be, for example, a numerical value proportional to the area corresponding to the recording-medium size.

For example, something that corresponds to a recording-medium type that represents the type of recording medium on which an image is printed on a target job, may be adopted as xₙ. For example, a value of an explanatory variable corresponding to the recording-medium type may be determined according to the recording-medium type, such as three for thick paper, two for plain paper, and one for thin paper. The value of the explanatory variable corresponding to the recording-medium type may be, for example, a numerical value proportional to a thickness corresponding to the recording-medium type. The explanatory variable corresponding to the recording-medium type may be provided for each recording-medium type. In the case in which the explanatory variable corresponding to the recording-medium type is provided for each recording-medium type, for example, the value of the explanatory variable for each recording-medium type may be one when a target recording-medium type is specified in a setting for a job, and may be zero when the target recording-medium type is not specified in the setting for the job. For example, in the case in which the explanatory variable corresponding to the recording-medium type is provided for each recording-medium type, a value of the explanatory variable for thick paper may be one when the thick paper is specified as the recording-medium type in a setting for a job, and may be zero when the thick paper is not specified as the recording-medium type in the setting for the job.

For example, something that corresponds to double-sided/single-sided, which represents which of double-sided printing and single-sided printing is to be performed on a target job, may be adopted as xₙ. For example, the value of the explanatory variable corresponding to double-sided/single-sided may be one when double-sided is specified in a setting for a job, and may be zero when single-sided is specified in the setting for the job.

For example, something that corresponds to color/monochrome, which represents which of color printing and monochrome printing is to be performed on a target job, may be adopted as xₙ. For example, a value of an explanatory variable corresponding to color/monochrome may be one when color is specified in a setting for a job, and may be zero when monochrome is specified in the setting for the job. Different explanatory variables corresponding to color/monochrome may be provided for color printing and monochrome printing. In the case in which different explanatory variables corresponding to color/monochrome are provided for color printing and monochrome printing, for example, the value of the explanatory variable for color printing may be one when the color printing is specified in a setting for a job, and may be zero when the color printing is not specified in the setting for the job. Likewise, in the case in which different explanatory variables corresponding to color/monochrome are provided for color printing and monochrome printing, for example, the value of the explanatory variable for monochrome printing may be one when the monochrome printing is specified in a setting for a job, and may be zero when the monochrome printing is not specified in the setting for the job.

For example, something that corresponds to integration representing the number of pages to be printed on one side of a recording medium, may be adopted as xₙ. For example, a value of an explanatory variable corresponding to integration may be eight when “no integration,” which indicates that the number of pages to be printed on one side of a recording medium is one, is specified in a setting for a job, and may be four when “2in1,” which indicates that the number of pages to be printed on one side of the recording medium is two, is specified in the setting for the job. The value of the explanatory variable corresponding to integration may be two when “4in1,” which indicates that the number of pages to be printed on one side of the recording medium is four, is specified in the setting for the job, and may be one when “8in1,” which indicates that the number of pages to be printed on one side of the recording medium is eight, is specified in the setting for the job.

When power consumption caused when the image forming apparatus 10 executes a job differs depending on a position of a medium supply portion that is supplied with a recording medium on which an image is printed on a target job, such as the case in which the number of times that a motor used to transport a recording medium is driven differs depending on the position of the medium supply portion supplied with a recording medium, something that corresponds to the position of the medium supply portion supplied with a recording medium on which an image is printed on a target job, may be adopted as xₙ.

When power consumption caused when the image forming apparatus 10 executes a job differs depending on a position of a medium discharge portion into which a recording medium on which an image is printed on a target job is discharged, such as the case in which the number of times that a motor used to transport a recording medium is driven differs depending on the position of the medium discharge portion into which a recording medium is discharged, something that corresponds to the position of the medium discharge portion into which a recording medium on which an image is printed on a target job is discharged, may be adopted as xₙ.

When the image forming apparatus 10 includes a function to perform post-processes, such as sorting, stapling, punching, and folding, with respect to a recording medium on which an image is printed, something that corresponds to the type of post-process performed on a recording medium on which an image is printed on a target job, may be adopted as xₙ.

xₙ may exist, for example, depending on a state of the image forming apparatus 10 when a target job is executed. For example, something that corresponds to an operation mode of the image forming apparatus 10 that corresponds to the state of the image forming apparatus 10 when a target job is executed, may be adopted as xₙ. Examples of the operation mode of the image forming apparatus 10 include a normal mode and a quiet mode that provides a quieter state than the normal mode. In the quiet mode, a motor used to rotate a polygon mirror in the printer 13 is stopped for a quiet state every time execution of a job is terminated. Thus, there is a need to drive, every time a job starts to be executed, the motor used to rotate the polygon mirror in the printer 13. Thus, more power consumption is caused in the quiet mode than in the normal mode.

b, which is a constant term, represents total electric power essentially necessary to execute a target job. For example, electric power used to increase, before printing, a temperature of a fixation roller included in the printer 13 up to a specific temperature and maintain the temperature of the fixation roller at the specific temperature, electric power used to stabilize, before printing, rotation of a motor used to rotate the fixation roller included in the printer 13, and electric power used to stabilize, before printing, rotation of a motor used to rotate a polygon mirror included in the printer 13 may be adopted as the electric power essentially necessary to execute a target job.

Next, a configuration of a carbon-dioxide-emission-estimating-model generating system used to generate the carbon dioxide emission estimating model is described.

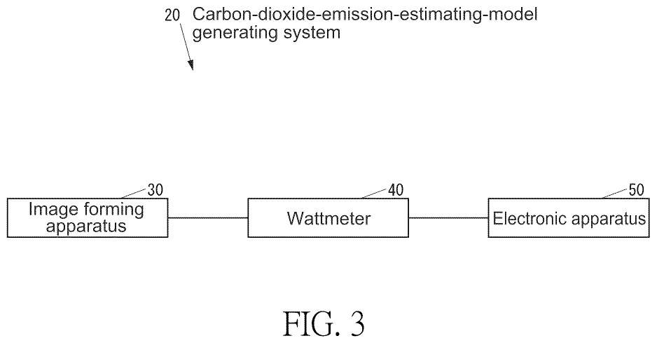

FIG. 3 is a block diagram of an example of a carbon-dioxide-emission-estimating-model generating system 20 used to generate the carbon dioxide emission estimating model used by the image forming apparatus 10.

As illustrated in FIG. 3, the carbon-dioxide-emission-estimating-model generating system 20 includes an image forming apparatus 30 of which an apparatus model is the same as an apparatus model of the image forming apparatus 10 (refer to FIG. 1), a wattmeter 40 that measures power consumption of the image forming apparatus 30, and an electronic apparatus 50, such as a smartphone or a tablet, that stores therein the power consumption measured by the wattmeter 40.

Next, a method for generating the carbon dioxide emission estimating model is described.

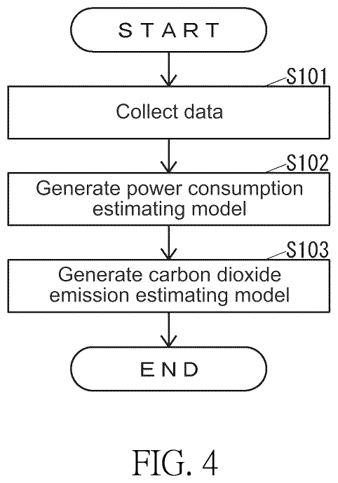

FIG. 4 is a flowchart of the method for generating the carbon dioxide emission estimating model used by the image forming apparatus 10.

As illustrated in FIG. 4, an operator collects (S101) a large number of pieces of data used to generate the power consumption estimating model. Specifically, the operator accumulates data in the electronic apparatus 50 for each setting for a job, where power consumption measured by the wattmeter 40 when the image forming apparatus 30 executes a job, and a setting for the job executed by the image forming apparatus 30 are included in the data in association with each other.

When the process of S101 is terminated, the operator generates (S102) a power consumption estimating model by multiple regression analysis performed using the data collected in S101. Specifically, the operator gives the electronic apparatus 50 an instruction to generate the power consumption estimating model by multiple regression analysis performed using the data collected in S101. Thus, the electronic apparatus 50 generates the power consumption estimating model by multiple regression analysis performed using the data collected in S101. The generation of the power consumption estimating model in S102 may be performed by machine learning.

When the process of S102 is terminated, the operator generates (S103) a carbon dioxide emission estimating model using the power consumption estimating model generated in S102. Specifically, the operator gives the electronic apparatus 50 an instruction to generate the carbon dioxide emission estimating model using the power consumption estimating model generated in S102. Thus, the electronic apparatus 50 generates the carbon dioxide emission estimating model by multiplying, by a coefficient of carbon dioxide emissions, the power consumption estimating model generated in S102.

In the carbon-dioxide-emission-estimating-model generating system 20 illustrated in FIG. 3, only a carbon dioxide emission estimating model for an image forming apparatus of which an apparatus model is the same as the apparatus model of the image forming apparatus 30 can be generated. Thus, a change in the apparatus model of an image forming apparatus in the carbon-dioxide-emission-estimating-model generating system 20 makes it possible to generate carbon dioxide emission estimating models for various apparatus models.

The carbon dioxide emission estimating model generated by the method illustrated in FIG. 4 may be installed on an image forming apparatus of which an apparatus model is the same as the apparatus model of the image forming apparatus 30 such as the image forming apparatus 10.

Next, an operation performed by the image forming apparatus 10 upon executing a job is described.

A copying job is described below as an example of the type of job. However, the same applies to a job other than the copying job.

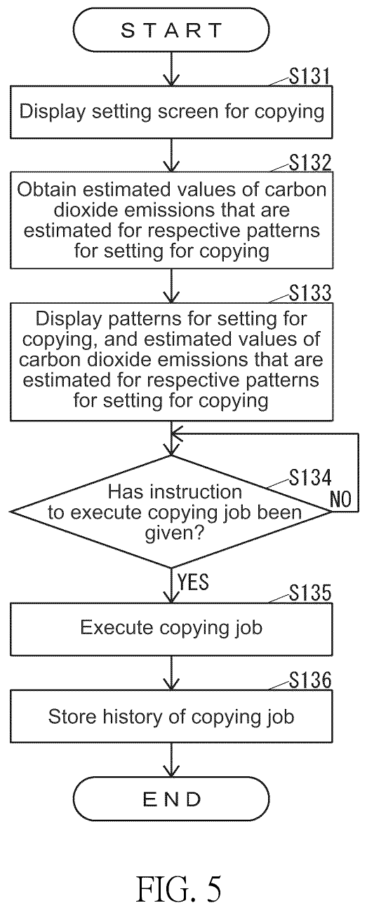

FIG. 5 is a flowchart of an operation performed by the image forming apparatus 10 upon executing a copying job.

When an instruction to display a setting screen for a copying job (hereinafter referred to as a “setting screen for copying”) is given through the operation section 11, the controller 18 of the image forming apparatus 10 displays (S131) the setting screen for copying on the display section 12, as illustrated in FIG. 5.

When the process of S131 is terminated, the carbon dioxide emission estimator 18a of the image forming apparatus 10 obtains (S132) estimated values of carbon dioxide emissions of the image forming apparatus 10 that are estimated for respective patterns of a plurality of patterns for a setting for the copying job (hereinafter referred to as a “setting for copying”), the estimated values being obtained using a carbon dioxide emission estimating model for the copying job and the patterns for the setting for copying.

When the process of S132 is terminated, the carbon dioxide emission estimator 18a displays (S133), on the setting screen for copying displayed in S131, the plurality of patterns for the setting for copying and the estimated values of carbon dioxide emissions of the image forming apparatus 10 that are estimated for the respective patterns of the plurality of patterns for the setting for copying and obtained in S132. Thus, when, for example, a user of the image forming apparatus 10 specifies the setting for copying by selecting one of the plurality of patterns for the setting for copying, the estimated values of carbon dioxide emissions of the image forming apparatus 10 are taken into consideration.

When the process of S133 is terminated, the controller 18 of the image forming apparatus 10 determines (S134) whether an instruction to execute the copying job has been given through the operation section 11, until the instruction to execute the copying job has been determined to be given through the operation section 11.

When the controller 18 determines, in S134, that the instruction to execute the copying job has been given through the operation section 11, the controller 18 executes (S135) the copying job using a setting for copying that is specified on the setting screen for copying.

When the process of S135 is terminated, the controller 18 stores (S136), in the job history information 17b, a history of the copying job executed in S135, and terminates the operation illustrated in FIG. 5.

In the operation illustrated in FIG. 5, the carbon dioxide emission estimator 18a displays estimated values of carbon dioxide emissions of the image forming apparatus 10 that are estimated for respective patterns of a plurality of patterns for a setting for copying. However, when a setting for copying is specified on a setting screen for copying, the carbon dioxide emission estimator 18a may obtain an estimated value of carbon dioxide emissions of the image forming apparatus 10, using the setting for copying specified on the setting screen for copying, and a carbon dioxide emission estimating model for a copying job, and may display the obtained estimated value on the setting screen for copying.

Next, an operation performed by the image forming apparatus 10 upon displaying a total of carbon dioxide emissions is described.

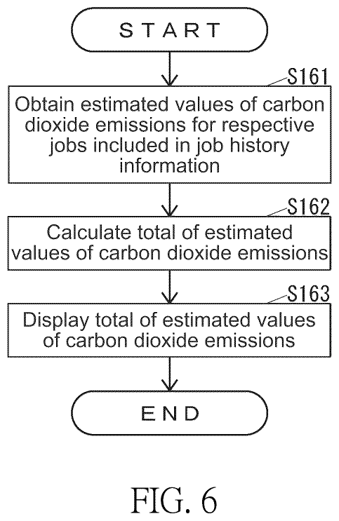

FIG. 6 is a flowchart of an operation performed by the image forming apparatus upon displaying a total of carbon dioxide emissions.

A user of the image forming apparatus 10 can give the image forming apparatus 10 an instruction to display, through the operation section 11, a total of carbon dioxide emissions of the image forming apparatus 10. When the instruction to display the total of the carbon dioxide emissions of the image forming apparatus 10 is given, the carbon dioxide emission estimator 18a of the image forming apparatus 10 obtains (S161), for each job included in the job history information 17b, an estimated value of carbon dioxide emissions of the image forming apparatus 10, using a setting for the job that is included in the job history information 17b, and a carbon dioxide emission estimating model corresponding to the type of the job that is included in the job history information 17b, as illustrated in FIG. 6.

When the process of S161 is terminated, the carbon dioxide emission estimator 18a adds all of the estimated values obtained in S161 to calculate (S162) the total of the estimated values of carbon dioxide emissions of the image forming apparatus 10.

When the process of S162 is terminated, the carbon dioxide emission estimator 18a displays (S163), on the display section 12, the total of the estimated values of carbon dioxide emissions of the image forming apparatus 10 that is calculated in S162. This enables the user of the image forming apparatus 10 to recognize the total of the estimated values of carbon dioxide emissions of the image forming apparatus 10.

In the operation illustrated in FIG. 6, the carbon dioxide emission estimator 18a displays totals of estimated values of carbon dioxide emissions of the image forming apparatus 10 that are obtained for all of periods of time in times past. However, the carbon dioxide emission estimator 18a may display a total of estimated values of carbon dioxide emissions of the image forming apparatus 10 that is obtained for a specific period of time, such as a period of time that is specified by the user of the image forming apparatus 10 through the operation section 11.

As described above, the image forming apparatus 10 obtains (S132 or S161) an estimated value of carbon dioxide emissions caused when the image forming apparatus 10 executes a job, using a carbon dioxide emission estimating model in which there exists a plurality of explanatory variables depending on the type of a setting for a job, and the setting for the job, where the carbon dioxide emission estimating model is represented by a formula in which an expression corresponding to a multiple regression formula used to obtain an estimated value of power consumption caused when the image forming apparatus 10 executes the job, is multiplied by a coefficient of carbon dioxide emissions. Thus, impacts on estimated values of carbon dioxide emissions of the image forming apparatus 10 for respective explanatory variables are not confused. This makes it possible to improve the accuracy of the estimated value of carbon dioxide emissions of the electronic apparatus 10.

The multiple regression formula used to obtain an estimated value of power consumption caused when the image forming apparatus 10 executes a job includes a constant term that represents total electric power essentially necessary to execute the job. Thus, the image forming apparatus 10 can obtain an estimated value of carbon dioxide emissions of the image forming apparatus 10, in consideration of an impact of the total electric power essentially necessary to execute the job. This makes it possible to improve the accuracy of the estimated value of carbon dioxide emissions of the electronic apparatus 10.

Without power consumption of the image forming apparatus 10 being measured by a wattmeter, the image forming apparatus 10 can obtain an estimated value of carbon dioxide emissions of the image forming apparatus 10, using a carbon dioxide emission estimating model.

A recording medium on which an image is printed by the image forming apparatus 10 is shipped in a state in which carbon dioxide emissions related to the recording medium are already calculated upon production of the recording medium. Likewise, toner used by the image forming apparatus 10 to perform printing on the recording medium is shipped in a state in which carbon dioxide emissions related to the toner are already calculated upon production of the toner. Thus, estimated values of carbon dioxide emissions for an amount of use of the recording medium and for an amount of use of the toner are not to be included in the estimated value of carbon dioxide emissions caused when the image forming apparatus 10 executes a job. Since the carbon dioxide emission estimator 18a does not include estimated values of carbon dioxide emissions for an amount of use of the recording medium and for an amount of use of the toner in an estimated value of carbon dioxide emissions caused when the image forming apparatus 10 executes a job, the accuracy of the estimated value of carbon dioxide emissions caused when the electronic apparatus 10 executes a job can be improved.

In the present embodiment, the carbon dioxide emission estimator 18a performs display to notify an estimated value of carbon dioxide emissions of the image forming apparatus 10. However, the carbon dioxide emission estimator 18a may notify the estimated value of carbon dioxide emissions of the image forming apparatus 10, using a method other than performing display. For example, the carbon dioxide emission estimator 18a may notify, using sound, the estimated value of carbon dioxide emissions of the image forming apparatus 10.

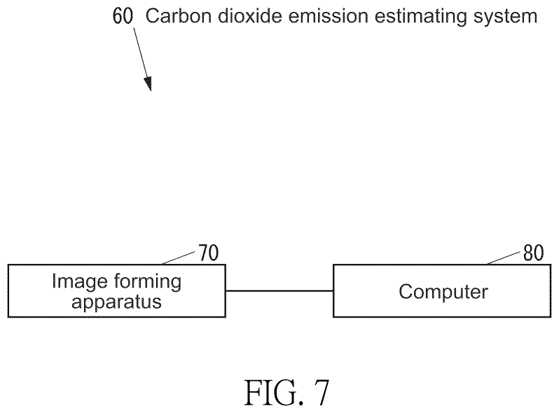

In the configuration described above, the carbon dioxide emission estimating system only includes the image forming apparatus. However, the carbon dioxide emission estimating system according to the present embodiment may include the image forming apparatus and at least one computer other than the image forming apparatus. For example, the carbon dioxide emission estimating system according to the present embodiment may have a configuration illustrated in FIG. 7.

FIG. 7 is a block diagram of an example of a carbon dioxide emission estimating system according to the present embodiment that is different from the example illustrated in FIG. 1.

A carbon dioxide emission estimating system 60 illustrated in FIG. 7 includes an image forming apparatus 70 and a computer 80. The image forming apparatus 70 and the computer 80 are communicably connected to each other. The computer 80 receives, from the image forming apparatus 70, the type of a job that is to be executed or has been executed by the image forming apparatus 70, and a setting for the job. As in the process of S132 or S161, the computer 80 obtains an estimated value of carbon dioxide emissions of the image forming apparatus 70 on the basis of the received type of job and the received setting for the job. The estimated value of carbon dioxide emissions of the image forming apparatus 70 that is obtained by the computer 80 may be notified by the image forming apparatus 70 or the computer 80.

In related art, carbon dioxide emissions for the type of paper and an amount of use of the paper, and carbon dioxide emissions for an amount of use of toner are calculated to be added in addition to carbon dioxide emissions caused by electric power being used. Each of the paper and the toner is shipped in a state in which the carbon dioxide emissions related to a corresponding one of the paper and the toner are already calculated upon its production. Thus, if carbon dioxide emissions related to paper and carbon dioxide emissions related to toner are included in carbon dioxide emissions caused by the image forming apparatus being used, the carbon dioxide emissions caused by the image forming apparatus being used will not be calculated accurately. When carbon dioxide emissions caused by electric power being used are calculated, power consumption caused by performing monochrome printing on a single A4-sized page and measured in advance using an internal module, or what is calculated from power consumption measured using a built-in wattmeter is held as reference electric power, and the reference power quantity is multiplied by a coefficient of print mode (color) and a layout coefficient to calculate power consumption. The calculated power consumption is multiplied by carbon dioxide emissions per unit power consumption to obtain carbon dioxide emissions. Actual measurement is necessary to determine reference electric power, and there is a need for an apparatus used to measure electric power. Further, it is difficult to measure power consumption accurately only using two kinds of coefficients that are the color coefficient and the layout coefficient.

In related art, carbon dioxide emissions for the type of paper and an amount of use of the paper, and carbon dioxide emissions for an amount of use of toner are calculated to be added in addition to carbon dioxide emissions caused by electric power being used. Each of the paper and the toner is shipped in a state in which the carbon dioxide emissions related to a corresponding one of the paper and the toner are already calculated upon its production. Thus, if carbon dioxide emissions related to paper and carbon dioxide emissions related to toner are included in carbon dioxide emissions caused by the image forming apparatus being used, the carbon dioxide emissions caused by the image forming apparatus being used will not be calculated accurately. When carbon dioxide emissions caused by electric power being used are calculated, power consumption of a mechanism section that operates depending on a setting for printing is calculated, and the number of times of operation performed by the operating mechanism section is determined by the number of sheets of paper printed and the number of sides on which printing is performed. Power consumption determined for each mechanism section is multiplied by a corresponding number of times of operation, and values obtained by the multiplication are added to calculate power consumption caused on a job. The calculated power consumption is multiplied by carbon dioxide emissions per unit power consumption to obtain carbon dioxide emissions caused by power consumption. There is a need to determine electric power for each operation portion, and to perform measurement in advance. Further, it is difficult to reflect factors that are not measured only using the number of times of operation. For example, if a printing speed is changed due to the paper size or the type of paper, electric power necessary to maintain a fixing temperature will be changed due to a change in printing time. Thus, it is difficult to perform prediction only using the number of times of operation.

On the other hand, the present embodiment makes it possible to estimate, without a power meter, power consumption of the image forming apparatus 10 per day from a set value of the image forming apparatus 10 and job execution information regarding the image forming apparatus 10, and thus to estimate carbon dioxide emissions. The formula represents not only the number of counts per day and a sleep power value of the image forming apparatus 10, but also hours of operation in a day for each status or for each type of job. In other words, the formula according to the present embodiment can represent use frequency or a use period by a time feature amount being introduced as an explanatory variable.

According to the present embodiment, a set value of the image forming apparatus, a counter value, execution information regarding execution of a job, and a log of the image forming apparatus are acquired. A regression model is generated on the basis of the acquired information, and consumption of power used by the image forming apparatus per day can be estimated using the model.

Carbon dioxide emissions can be calculated by multiplying power consumption by the coefficient of carbon dioxide emissions that is defined by the Ministry of the Environment. Thus, carbon dioxide emissions can be derived by power consumption of the image forming apparatus being estimated.

The intended use of the image forming apparatus is execution of jobs such as copying and printing, and most power consumption is considered to be caused due to the execution of jobs. Actually, power consumption can be estimated with a higher degree of accuracy using a sleep condition and a heater-related potion of set values, in addition to the execution of jobs.

According to the present embodiment, the image forming apparatus obtains an estimated value of carbon dioxide emissions caused when the image forming apparatus executes a job, using a carbon dioxide emission estimating model in which there exists a plurality of explanatory variables depending on the type of a setting for a job, and the setting for the job, where the carbon dioxide emission estimating model is represented by a formula in which an expression corresponding to a multiple regression formula used to obtain an estimated value of power consumption caused when the image forming apparatus executes the job, is multiplied by a coefficient of carbon dioxide emissions. Thus, impacts on estimated values of carbon dioxide emissions of the image forming apparatus for respective explanatory variables are not confused. This makes it possible to improve the accuracy of the estimated value of carbon dioxide emissions of the electronic apparatus.

According to the present embodiment, the multiple regression formula used to obtain an estimated value of power consumption caused when the image forming apparatus executes a job includes a constant term that represents total electric power essentially necessary to execute the job. Thus, the image forming apparatus can obtain an estimated value of carbon dioxide emissions of the image forming apparatus, in consideration of an impact of the total electric power essentially necessary to execute the job. This makes it possible to improve the accuracy of the estimated value of carbon dioxide emissions of the electronic apparatus.

Further, according to the present embodiment, the multiplication of execution information regarding execution of a job or a variable of a set value by a variable representing time makes it possible to also take into consideration a time taken to execute the job and a period of time for which a sleep state remains unchanged, compared to existing technologies. This makes it possible to estimate carbon dioxide emissions with a higher degree of accuracy. In particular, a state in which an apparatus itself is consuming power but is not executing a job (such as only a panel is touched, and an error has occurred) can also be taken into consideration. This will bring a great advantage.

Although each embodiment and each modified example of the present technology have been described above, the present technology is not limited to the above-mentioned embodiments, and various modifications can be made without departing from the gist of the present technology as a matter of course.

What is claimed is:

1. An electronic apparatus, comprising
a carbon dioxide emission estimator that obtains an estimated value of carbon dioxide emissions caused when the electronic apparatus executes a job, using a carbon dioxide emission estimating model represented by a formula used to estimate the carbon dioxide emissions, and a setting for the job, wherein
the carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions,
with respect to an explanatory variable in the carbon dioxide emission estimating model, there exists a plurality of the explanatory variables depending on a type of the setting for the job or a state of the electronic apparatus,
the explanatory variable represents a time feature amount of a time taken for the job or duration of the state, and
the carbon dioxide emission estimating model represents use frequency or a use period using the time feature amount.

2. The electronic apparatus according to claim 1, wherein
the multiple regression formula includes a constant term that represents total electric power essentially necessary to execute the job.

3. The electronic apparatus according to claim 1, wherein
the carbon dioxide emission estimating model is represented by the following formula:
$${CO}_{2} emissions = \{ {( {a}_{y} )}^{{y}^{′}} - {n}_{y} \} \times coefficient of {CO}_{2} emissions \\ ( {y}^{′} = ) {log}_{{a}_{y}} ( y + {n}_{y} ) = a + {\sum }_{k = 1}^{l} {b}_{k}^{t} {t}_{k}^{t} {log}_{{a}_{T}} ( T ) {log}_{{a}_{k}^{t}} ( {x}_{k}^{t} + {n}_{k} ) + {\sum }_{k = 1}^{𝔪} {b}_{k}^{o} {t}_{k}^{o} {log}_{{a}_{k}^{o}} ( {x}_{k}^{o} + {n}_{k} ) + {\sum }_{k = 1}^{n} {t}_{k}^{s} {b}_{k}^{s} {x}_{k}^{s}$$
where
y represents power consumption,
y′ represents logarithmized power consumption,
a represents a constant term,
$${x}_{k}^{t}$$
represents a job-execution-information variable, such as the number of sheets of paper printed or the number of sheets of paper copied, that is related to a TEC value,
$${x}_{k}^{o}$$
represents a job-execution-information variable, such as a percentage of color printing or the number of times of scanning, that is not related to the TEC value,
$${x}_{k}^{s}$$
represents an explanatory variable for a set value, such as light sleep, deep sleep, or a drum-heater setting,
$${t}_{k}^{t} , {t}_{k}^{o} , and {t}_{k}^{s}$$
each represent a time taken for each job such as printing or copying, or a period of time for which each state such as light sleep or deep sleep remains unchanged,
n_{y} and nₖ each represent an offset value for logarithmic transform,
a_{y}, a_{T},
$${a}_{k}^{t} , and {a}_{k}^{o}$$
represent bases of respective logarithms,
Tₖ represents the TEC value, and
$${b}_{k}^{x}$$
represents a partial regression coefficient.

4. A non-transitory computer-readable recording medium that has recorded therein a carbon dioxide emission estimating program that causes a control circuit of an electronic apparatus to operate as a carbon dioxide emission estimator that obtains an estimated value of carbon dioxide emissions caused when the electronic apparatus executes a job, using a carbon dioxide emission estimating model represented by a formula used to estimate the carbon dioxide emissions, and a setting for the job, wherein
the carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions,
with respect to an explanatory variable in the carbon dioxide emission estimating model, there exists a plurality of the explanatory variables depending on a type of the setting for the job or a state of the electronic apparatus,
the explanatory variable represents a time feature amount of a time taken for the job or duration of the state, and
the carbon dioxide emission estimating model represents use frequency or a use period using the time feature amount.

5. A carbon dioxide emission estimating method that is performed by a carbon dioxide emission estimating program being executed by a control circuit of an electronic apparatus, the carbon dioxide emission estimating method comprising obtaining an estimated value of carbon dioxide emissions caused when the electronic apparatus executes a job, using a carbon dioxide emission estimating model represented by a formula used to estimate the carbon dioxide emissions, and a setting for the job, wherein
the carbon dioxide emission estimating model is represented by the formula in which an expression corresponding to a multiple regression formula used to obtain an estimated value of power consumption caused when the electronic apparatus executes the job, is multiplied by a coefficient of carbon dioxide emissions,
with respect to an explanatory variable in the carbon dioxide emission estimating model, there exists a plurality of the explanatory variables depending on a type of the setting for the job or a state of the electronic apparatus,
the explanatory variable represents a time feature amount of a time taken for the job or duration of the state, and
the carbon dioxide emission estimating model represents use frequency or a use period using the time feature amount.
